(19) United States
(12) Patent Application Publication
(10) Pub. No.: US 2011/0094788 A1
(43) Pub. Date: Apr. 28, 2011

(54) PRINTED CIRCUIT BOARD WITH INSULATING AREAS

(75) Inventors: KAI-FANG CHEN, Shanghai (CN); CHIEH-YEN HUANG, Tu-Cheng City (TW); LI-PING CHEN, Shanghai (CN)

(73) Assignees: AMBIT MICROSYSTEMS (SHANGHAI) LTD., SHANGHAI (CN); HON HAI PRECISION INDUSTRY CO., LTD., Tu-Cheng (TW)

(21) Appl. No.: 12/649,544

(22) Filed: Dec. 30, 2009

(30) Foreign Application Priority Data
Oct. 28, 2009 (CN) 200920313462.3

(51) Int. Cl. H05K 1/11

(52) U.S. Cl. 174/266

(57) ABSTRACT

A printed circuit board includes a substrate including a first surface and a second surface opposite to the first surface, a pair of first pads positioned on the first surface and the second surface, and a plurality of insulating areas. The substrate defines a through hole and a plurality of vias extending from the first surface to the second surface. Each of the pair of first pads surrounds the through hole. The insulating areas are adjacent to the first pad to divide a reference metal layer of the substrate adjacent to the first pads into a plurality of metal strips to reduce heat dissipation area of the reference metal layer adjacent to the first pads. The vias are adjacent to the metal strips to supply extra heat to molten solder on the first surface in a wave-soldering process.

### BACKGROUND

1. Technical Field

The present disclosure relates to a printed circuit board, and specifically to a printed circuit board with insulating areas.

2. Description of Related Art

A typical electrical device generally includes a printed circuit board (PCB) on which a plurality of components, such as resistors, capacitors, and/or Dual In-line Package (DIP) components, etc., are mounted. A component is generally mounted to the printed circuit board by component pins being received in through-holes defined in the printed circuit board, and later being soldered on the printed circuit board in a wave-soldering process. The pins of the component are electrically connected to a reference layer, such as a solid copper layer, of the PCB. However, in the wave-soldering process, the reference layer of the PCB dissipates heat quickly due to a large surface area of copper, causing cold soldering or poor soldering of the component.

Therefore, a need exists in the industry to overcome the described limitations.

### BRIEF DESCRIPTION OF THE DRAWINGS

FIG. 1 is a plan view of a printed circuit board of an exemplary embodiment of the disclosure.

FIG. 2 is an inverted view of FIG. 1.

### DETAILED DESCRIPTION

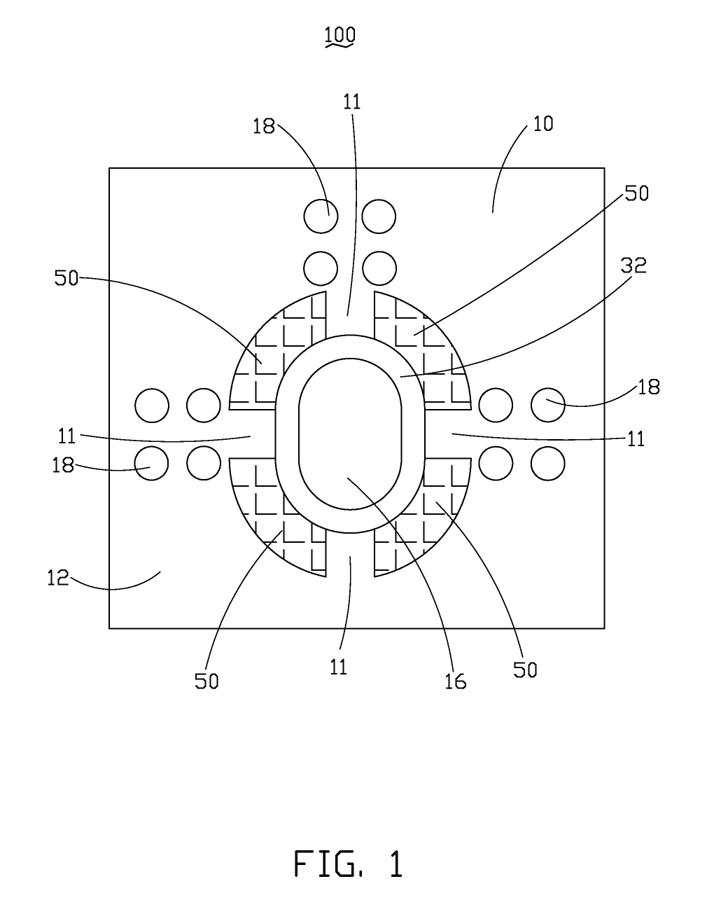

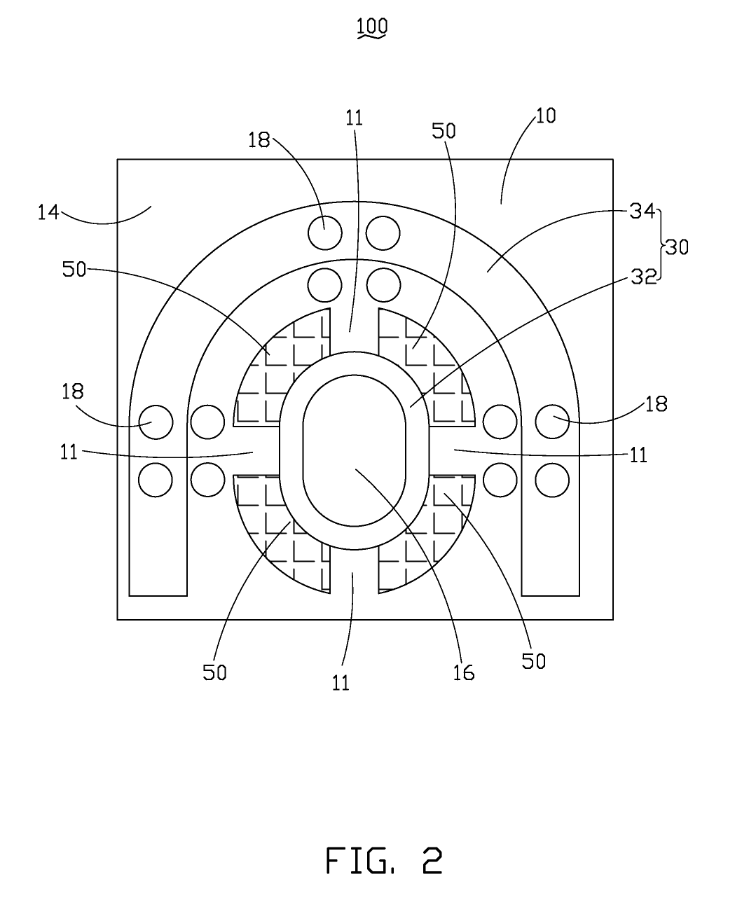

Referring to FIG. 1 and FIG. 2, a printed circuit board 100 of an exemplary embodiment of the present disclosure is illustrated. The printed circuit board 100 includes a substrate 10, a pad portion 30, and a plurality of insulating areas 50.

The substrate 10 includes a first surface 12, a second surface 14 opposite to the first surface 12, a through hole 16, and a plurality of vias 18. The through hole 16 and the plurality of vias 18 extend from the first surface 12 to the second surface 14. A component (not shown), such as a resistor, a capacitor, and/or a Dual In-line Package (DIP) component, for example, is soldered on the substrate 10 by a pin of the component being received in through-hole 16 in a wave-soldering process. The through hole 16 is generally elliptical. An inner wall of the through-hole 16 is coated with copper foils.

The pad portion 30 includes a pair of opposite first pads 32 surrounding the through hole 16, and a second pad 34. One of the pair of first pads 32 is arranged on the first surface 12, and the other is arranged on the second surface 14. The center of each of the pair of first pads 32 is the same as the center of the through hole 16. In the illustrated embodiment, the pair of first pads 32 and the second pad 34 are copper foils.

The second pad 34 is substantially U-shaped. The second pad 34 is arranged on the second surface 14, and surrounds the plurality of insulating areas 50. In the wave-soldering process, the second surface 14 absorbs heat to slow heat dissipation of molten solder of the first surface 12, so that the molten solder of the first surface 12 can adhere normally to the pin of the component, reducing cold soldering or poor soldering of the component. Alternatively, the printed circuit board 100 may not include the second pad 34.

The plurality of insulating areas 50 divide a reference metal layer (not labeled) of the substrate 10 adjacent to the pair of first pads 32, such as a solid copper layer, into a plurality of metal strips 11, for example copper strips. The pair of first pads 32 are electrically connected to the reference metal layer of the substrate 10 by the plurality of copper strips 11. That is, the heat dissipation area of the reference metal layer adjacent to the pair of first pads 32 is reduced, so that heat dissipation of the molten solder of the first surface 12 is slowed in the wave-soldering process, reducing cold soldering or poor soldering of the component.

In the illustrated embodiment, each of the plurality of insulating areas 50 is substantially fan-shaped. The center of each of the insulating areas 50 is the same as the center of the through hole 16 or each of the pair of first pads 32. Each of the plurality of insulating areas 50 is an etched hollow area between the reference metal layer and each of the pair of first pads 32. Alternatively, each of the plurality of etched hollow areas can be filled with an insulation material.

Inner walls of the plurality of vias 18 are coated with solder mask to avoid adhesion of solder thereto when the component is soldered on the substrate 10, reducing waste of solder. In the illustrated embodiment, the plurality of vias 18 are divided into three groups. Each of the three groups of vias 18 includes four vias 18 arranged in two columns adjacent to each of the copper strips 11, wherein one column of vias 18 is positioned in the second pad 34 and the other column of vias 18 is arranged between the second pad 34 and the plurality of insulating areas 50. In the wave-soldering process, the plurality of vias 18 spread heat in the second surface 14 to the first surface 12. That is, the plurality of vias 18 supply extra heat to the molten solder of the first surface 12 to slow heat dissipation of the molten solder of the first surface 12 in the wave-soldering process, reducing poor soldering or cold soldering of the component.

Because the printed circuit board 100 includes the plurality of insulating areas 50 and the plurality of vias 18, heat dissipation of the molten solder of the first surface 12 is slowed in the wave-soldering process, reducing cold soldering or poor soldering of the component.

While an embodiment of the present disclosure has been described above, it should be understood that it has been presented by way of example only and not by way of limitation. Thus the breadth and scope of the present disclosure should not be limited by the above-described embodiments, but should be defined only in accordance with the following claims and their equivalents.

What is claimed is:

1. A printed circuit board, comprising:
a substrate comprising a first surface, a second surface opposite to the first surface, a through hole, and a plurality of vias, wherein the through hole and the plurality of vias extend from the first surface to the second surface;
a pair of opposite first pads surrounding the through hole, wherein one of the pair of first pads is arranged on the first surface, and the other is arranged on the second surface; and
a plurality of insulating areas adjacent to the pair of first pads to divide a reference metal layer of the substrate adjacent to the pair of first pads into a plurality of metal strips to reduce heat dissipation area of the reference metal layer adjacent to the pair of first pads;
wherein the plurality of vias are adjacent to the metal strips to supply extra heat to molten solder on the first surface in a wave-soldering process.

2. The printed circuit board as recited in claim 1, further comprising a second pad arranged on the second surface, wherein the second pad surrounds the plurality of insulating areas.

3. The printed circuit board as recited in claim 1, wherein each of the plurality of insulating areas is substantially fan-shaped.

4. The printed circuit board as recited in claim 3, wherein a center of each of the plurality of insulating areas is the same as a center of the through hole.

5. The printed circuit board as recited in claim 4, wherein each of the plurality of insulating areas is an etched hollow area between the reference metal layer and the pair of first pads.

6. The printed circuit board as recited in claim 5, wherein each of the plurality of etched hollow areas is filled with an insulation material.

7. The printed circuit board as recited in claim 1, wherein an inner wall of each of the plurality of vias is coated with solder mask.
